(19) United States
(12) Patent Application Publication
(10) Pub. No.: US 2021/0203050 A1
(43) Pub. Date: Jul. 1, 2021

(54) METHOD FOR ESTABLISHING ULTRA WIDE BAND CLASS I CHEBYSHEV MULTI-SECTION WILKINSON POWER DIVIDER HAVING EQUAL RIPPLE ISOLATION CHARACTERISTIC

(71) Applicant: JILIN UNIVERSITY, Changchun (CN)

(72) Inventors: Xiaolong WANG, CHANGCHUN (CN); Zizhuo SUN, CHANGCHUN (CN); Bin WU, CHANGCHUN (CN); Geyu LU, CHANGCHUN (CN)

(21) Appl. No.: 16/994,564

(22) Filed: Aug. 15, 2020

(30) Foreign Application Priority Data
Dec. 30, 2019 (CN) 201911391859.9

(51) Int. Cl. H01P 1/213; H03F 1/42; H03F 1/56

(52) U.S. Cl. CPC H01P 1/2135; H01Q 5/25; H03F 1/56; H03F 1/42

(57) ABSTRACT

The disclosure discloses a method for establishing an ultra wide band (UWB) class I Chebyshev multi-section Wilkinson power divider having equal ripple isolation characteristic, including: step 1, determining a Chebyshev equal ripple order required in the designed circuit and calculating a class I Chebyshev polynomial in the same order, and meanwhile determining the equal ripple heights of S₁₁ and S₃₂; step 2, carrying out even-mode analysis on the power divider, calculating an ABCD matrix expression under the even-mode condition according to the Chebyshev equal ripple order and the number of the required coupled line units, calculating equivalent conditions, and then obtaining a Zₑᵥ impedance value of each section of coupled line; step 3, carrying out odd-mode analysis on the power divider so that each zero position and each peak ripple position of S₃₂ and S₁₁ are the same.

### CROSS-REFERENCE TO RELATED APPLICATIONS

This application claims priority to Chinese Patent Application No. 201911391859.9 with a filing date of Dec. 30, 2019. The content of the aforementioned applications, including any intervening amendments thereto, are incorporated herein by reference.

### TECHNICAL FIELD

The disclosure belongs to the technical field of radio-frequency circuit microstrip line device manufacturing, and particularly relates to a method for establishing an ultra wide band (UWB) class I Chebyshev multi-section Wilkinson power divider having equal ripple isolation characteristic.

### BACKGROUND OF THE PRESENT INVENTION

A Wilkinson power divider is widely applied to microwave circuits and systems. For different applications, many types of power dividers have occurred in recent years. For a single-band power divider, transmission line and coupling line structures are applied to inhibit higher harmonic waves and control a power allocation ratio. Since Monzon proposed a dual-band impedance transformer, many dual-band power dividers are realized based on a structure with two sections of transmission lines or coupled lines. triple-band, multi-band, filter-type and tunable/reconfigurable power dividers are also well researched.

In 2002, federal communications commission issued information about use of ultra wide band (UWB) wireless systems (from 3.1 to 10.6 GHz), attracting attentions from many researchers. For many UWB devices, like a filter Balun (balance-unbalance signal converter, generally used between an antenna and a receiver), power dividers composed of transmission lines and coupled lines have been deeply researched in recent years.

In the prior art, a UWB power divider composed of stepped impedance open stubs and parallel coupled transmission lines is reported, which can provide performances of in-band separation and isolation. Meanwhile, a special ring resonator structure is also reported, which can generate extra transmission zero and inhibit resulting harmonic waves; however, some relationships in a topology of a multi-section UWB power divider have not been yet analyzed and discussed in detail, for example design methods of equal ripple response of UWB power dividers.

### SUMMARY OF PRESENT INVENTION

The disclosure designs and discloses a method for establishing an ultra wide band (UWB) class I Chebyshev multi-section Wilkinson power divider having equal ripple isolation characteristic. The objective of the disclosure is to establish the divider of the disclosure so that a transmission function and an isolation function can simultaneously realize equal ripple response, wherein the transmission function realizes Chebyshev equal ripple response, and the transmission function and the isolation function are the same in dead-center position and peak ripple position and can realize large bandwidth response and perfect isolation characteristic on the premise of a compact size.

The technical solution provided by the disclosure is as follows:

A method for establishing an ultra wide band class I Chebyshev multi-section Wilkinson power divider having equal ripple isolation characteristic, comprising the following steps:

step 1, determining a Chebyshev equal ripple order required in the designed circuit and calculating a class I Chebyshev polynomial in the same order, and meanwhile determining the equal ripple heights of reflection function S₁₁ and isolation function S₃₂;

step 2, carrying out even-mode analysis on the power divider, selecting a model according to the Chebyshev order so as to calculate an ABCD matrix expression under the even-mode condition, calculating equivalent conditions according to the ABCD matrix expression and the class I Chebyshev polynomial so that the designed circuit satisfies the structure of the Chebyshev polynomial and then a Zᵢₑ impedance value of each section of coupled line is obtained;

step 3, carrying out odd mode analysis on the power divider so that each zero dead-center position and peak ripple position of the isolation function S₃₂ and the reflection function S₁₁ are the same and then the Zᵢₒ impedance value of each section of coupled line and the impedance value of each isolation resistor are obtained; and

step 4, establishing a final circuit according to the Zᵢₑ impedance value, the Zᵢₒ impedance value and the impedance value of each isolation resistor.

Preferably, in the step 1, the Chebyshev equal ripple order is the number of the coupled lines.

Preferably, in the step 2, a coupled line unit is composed of one section of transmission line with a characteristic impedance as Zᵢₑ under the condition of even-mode analysis.

Preferably, in the step 1, the class I Chebyshev polynomial is T_{N}=2×T_{N-1}(x)−T_{N-2}(x); wherein, T₀(χ)=1; T₁(χ)=χ.

Preferably, in the step 2, the even mode ABCD matrix of N cascaded coupled line units is:

$$[ \begin{matrix}{A}_{ev} & {B}_{ev} \\ {C}_{ev} & {D}_{ev}\end{matrix} ] = [ \begin{matrix}{A}_{Ne} & {B}_{Ne} \\ {C}_{Ne} & {D}_{Ne}\end{matrix} ] ⋯ [ \begin{matrix}{A}_{2 e} & {B}_{2 e} \\ {C}_{2 e} & {D}_{2 e}\end{matrix} ] [ \begin{matrix}{A}_{1 e} & {B}_{1 e} \\ {C}_{1 e} & {D}_{1 e}\end{matrix} ] ;$$

wherein, when N is odd:

$${A}_{ev} = {a}_{Ne} {cos}^{N} θ + ⋯ + {a}_{3 e} {cos}^{3} θ + {a}_{1 e} {cos}^{1} θ$$

$${B}_{ev} = \frac{j}{sinθ} ( {b}_{N + 1 e} {cos}^{N + 1} θ + ⋯ + {b}_{2 e} {cos}^{2} θ + {b}_{0 e} {cos}^{0} θ )$$

$${C}_{ev} = \frac{j}{sinθ} ( {c}_{N + 1 e} {cos}^{N + 1} θ + ⋯ + {c}_{2 e} {cos}^{2} θ + {c}_{0 e} {cos}^{0} θ )$$

$${D}_{ev} = {d}_{Ne} {cos}^{N} θ + ⋯ + {d}_{3 e} {cos}^{3} θ + {d}_{1 e} {cos}^{1} θ ;$$

when N is even:

$${A}_{e v} = {a}_{N e} {cos}^{N} θ + … + {a}_{2 e} {cos}^{2} θ + {a}_{0 e} {cos}^{0} θ \\ {B}_{e v} = \frac{j}{sin θ} ( {b}_{N + 1 e} {cos}^{N + 1} θ + … + {b}_{3 e} {cos}^{3} θ + {b}_{1 e} {cos}^{1} θ )$$

$${C}_{e v} = \frac{j}{sin θ} ( {c}_{N + 1 e} {cos}^{N + 1} θ + … + {c}_{3 e} {cos}^{3} θ + {c}_{1 e} {cos}^{1} θ )$$

$${D}_{e v} = {d}_{N e} {cos}^{N} θ + … + {d}_{2 e} {cos}^{2} θ + {d}_{0 e} {cos}^{0} θ$$

in the formulas, a_{Ne}, b_{Ne}, c_{Ne} and d_{Ne} are respectively polynomial coefficients whose numbers of times are n (n∈0, 1, 2, N, N+1).

Preferably, in the step 2, the equivalent condition is that a transmission function S₂₁ calculated by the even mode ABCD matrix of the N cascaded coupling line units is equal to a transmission function S₂₁ calculated through the Chebyshev polynomial.

Preferably, in the step 2, the source terminal impedance value Zₛ and the load terminal impedance value Z_{L} of the circuit are determined, and Z_{S}/Z_{L}=2; and the transmission function S₂₁ calculated by the even-mode ABCD matrix of the N cascaded coupled line units is:

$${\vert {S}_{21} \vert}^{2} = \frac{1}{1 + {\vert {F}_{e v} \vert}^{2}} ;$$

$$wherein , {F}_{e v} = \frac{{S}_{11}}{{S}_{21}} = \frac{2 {A}_{e v} + {B}_{e v} / {Z}_{0} - 2 {Z}_{0} {C}_{e v} - {D}_{e v}}{2 \sqrt{2}} ;$$

and

the transmission function calculated by the Chebyshev polynomial is

$${\vert {S}_{21} \vert}^{2} = \frac{1}{1 + {\vert {F}_{e v} \vert}^{2}} ;$$

$$wherein , \vert {F}_{e v} \vert = ɛ \vert cos ( N ϕ ) \vert = ɛ \vert {\sum }_{n = 1}^{N} \frac{{cos}^{n} θ}{{cos}^{n} {θ}_{c}^{S 11}} \vert .$$

Preferably, in the step 3, the coupling line unit is composed of one section of transmission line with a characteristic impedance as Zᵢₒ and one resistor with an impedance as Rᵢ/2 under the condition of odd-mode analysis.

Preferably, in the step 3, the odd-mode ABCD matrix of the N cascaded coupled line units is

$$[ \begin{matrix}{A}_{o d} & {B}_{o d} \\ {C}_{o d} & {D}_{d}\end{matrix} ] = [ \begin{matrix}{A}_{N o} & {B}_{No} \\ {C}_{No} & {D}_{No}\end{matrix} ] … [ \begin{matrix}{A}_{2 o} & {B}_{2 o} \\ {C}_{2 o} & {D}_{2 o}\end{matrix} ] [ \begin{matrix}{A}_{1 o} & {B}_{1 o} \\ {C}_{l o} & {D}_{1 o}\end{matrix} ] ;$$

wherein, when N is odd:

$${A}_{od} = {a}_{Nor} {cos}^{N} θ + … + {a}_{3 or} {cos}^{3} θ + {a}_{1 or} {cos}^{1} θ + \frac{j}{sin θ} ( {a}_{N + 1 oi} {cos}^{N + 1} θ + … {a}_{2 oi} {cos}^{2} θ + {a}_{0 oi} {cos}^{0} θ )$$

$${B}_{od} = {b}_{N o r} {cos}^{N} θ + … + {b}_{3 o r} {cos}^{3} θ + {b}_{1 o r} {cos}^{1} θ + \frac{j}{sin θ} ( {b}_{N + 1 oi} {cos}^{N + 1} θ + … {b}_{2 oi} {cos}^{2} θ + {b}_{0 oi} {cos}^{0} θ ) \\ {C}_{od} = {c}_{N o r} {cos}^{N} θ + … + {c}_{3 o r} {cos}^{3} θ + {c}_{1 or} {cos}^{1} θ + \frac{j}{sin θ} ( {c}_{N + 1 oi} {cos}^{N + 1} θ + … {c}_{2 oi} {cos}^{2} θ + {c}_{0 oi} {cos}^{0} θ ) \\ {D}_{od} = {d}_{Nor} {cos}^{N} θ + … + {d}_{3 o r} {cos}^{3} θ + {d}_{1 or} {cos}^{1} θ + \frac{j}{sin θ} ( {d}_{N + 1 oi} {cos}^{N + 1} θ + … {d}_{2 oi} {cos}^{2} θ + {d}_{0 oi} {cos}^{0} θ )$$

when N is even:

$${A}_{od} = {a}_{Nor} {cos}^{N} θ + … + {a}_{2 or} {cos}^{2} θ + {a}_{0 or} {cos}^{0} θ + \frac{j}{sin θ} ( {a}_{N + 1 oi} {cos}^{N + 1} θ + … {a}_{3 oi} {cos}^{3} θ + {a}_{0 oi} {cos}^{1} θ )$$

$${B}_{od} = {b}_{N o r} {cos}^{N} θ + … + {b}_{2 or} {cos}^{2} θ + {b}_{0 or} {cos}^{0} θ + \frac{j}{sin θ} ( {b}_{N + 1 oi} {cos}^{N + 1} θ + … {b}_{3 oi} {cos}^{3} θ + {b}_{1 oi} {cos}^{1} θ ) \\ {C}_{od} = {c}_{N o r} {cos}^{N} θ + … + {c}_{2 or} {cos}^{2} θ + {c}_{0 or} {cos}^{0} θ + \frac{j}{sin θ} ( {c}_{N + 1 oi} {cos}^{N + 1} θ + … {c}_{3 oi} {cos}^{3} θ + {c}_{1 oi} {cos}^{1} θ ) \\ {D}_{od} = {d}_{Nor} {cos}^{N} θ + … + {d}_{2 or} {cos}^{2} θ + {d}_{0 or} {cos}^{0} θ + \frac{j}{sin θ} ( {d}_{N + 1 oi} {cos}^{N + 1} θ + … {d}_{3 oi} {cos}^{3} θ + {d}_{1 oi} {cos}^{1} θ )$$

in the formulas, a_{Nor}, b_{Nor}, c_{Nor} and d_{Nor} as well as a_{Noi}, b_{Noi}, c_{Noi} and d_{Noi} are respectively polynomials whose numbers of times are n, (n∈0, 1, 2, . . . , N, N+1).

Compared with the prior art, the disclosure has the beneficial effects:

1. The coupled lines are cascaded to form a multi-section Wilkinson power divider. A resistor having a specific impedance value is connected between each coupled line so as to provide perfect isolation characteristic;

2. The transmission function (S₂₁) and the isolation function (S₂₃) can simultaneously achieve equal ripple response, and the transmission function (S₂₁) is constrained as the class I Chebyshev polynomial to achieve equal ripple response;

3. The reflection function (S₂₁) and the isolation function (S₂₃) can be independently regulated, and the reflection zeros are consistent with the isolation zeros, that is, the peak positions of the ripples are consistent;

4. As a multi-section Wilkinson power divider, the working bandwidth can be flexibly increased by increasing the section number of the cascaded coupled lines.

5. In general, the Wilkinson power divider is formed by combining up and down transmission lines. However, under the condition that the section number of the power divider is increased, horizontal and vertical sizes can be greatly increased. Based on the requirement of reducing the size as much as possible, the disclosure uses a structure with cascaded coupled lines, thereby effectively reducing the longitudinal size.

### DESCRIPTION OF THE DRAWINGS

FIG. 1 is a flowchart of a method for establishing an ultra wide band multi-section Wilkinson power divider according to the disclosure.

FIG. 2 is a diagram of a relationship among Chebyshev ripple type, electrical length θc^{S11} and section number N.

FIG. 3 is a diagram of a topological structure of an ultra wide band multi-section Wilkinson power divider according to the disclosure.

FIG. 4 is a diagram of an even-mode equivalent circuit of a multi-section Wilkinson power divider according to the disclosure.

FIG. 5 is a diagram of an odd-mode equivalent circuit of a multi-section Wilkinson power divider according to the disclosure.

FIG. 6 is a diagram showing general equal ripple response of a reflection function S₁₁ and an isolation function S₃₂ according to the disclosure.

FIG. 7 is a diagram of a topological structure of a three-section ultra wide band Wilkinson power divider according to the disclosure.

FIG. 8 is a circuit simulation diagram of a three-section ultra wide band power divider under the ripple grade in example 1 of the disclosure.

FIG. 9 is a circuit simulation diagram of a three-section ultra wide band power divider under the ripple grade in example 2 of the disclosure.

FIG. 10 is a circuit simulation diagram of a three-section ultra wide band power divider under the ripple grade in example 3 of the disclosure.

FIG. 11 is a diagram of a design circuit in a test example according to the disclosure.

FIG. 12 is a diagram of circuit simulation, electromagnetic field simulation and test results of a reflection function S₁₁ and a transmission function S₂₁ of port 1 according to the disclosure.

FIG. 13 is a diagram of circuit simulation, electromagnetic field simulation and test results of a reflection function S₂₂ and an isolation function S₃₂ of port 2 according to the disclosure.

### DETAILED DESCRIPTION OF PREFERRED EMBODIMENTS

Next, the disclosure will be described in detail in combination with drawings so as to be implemented by those skilled in the art with reference to words of the specification.

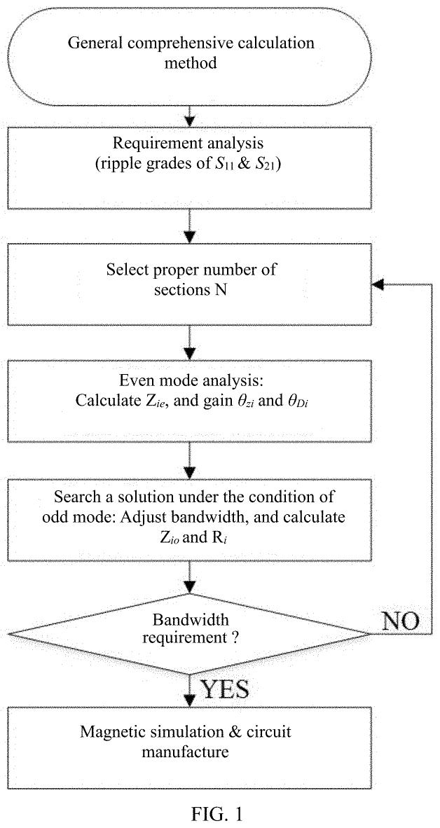

As shown in FIG. 1, the disclosure provides a method for establishing an ultra wide band class I Chebyshev multi-section Wilkinson power divider having equal ripple isolation characteristic, comprising the following steps:

step 1, a Chebyshev equal ripple order (namely the number of ripples and the number of transmission zeros in a reflection function S₁₁ are determined) required in the designed circuit, the equal ripple heights (namely return loss) of the reflection function S₁₁ and the isolation function S₃₂ are determined, and odd-even mode analysis is carried out on the power divider;

step 2, under the even-mode analysis, the source terminal impedance Z_{S} of a circuit is 100Ω, the load terminal impedance Z_{L} of the circuit is 50Ω, and a model is selected according to the determined Chebyshev equal ripple order so as to calculate an ABCD matrix expression under the condition of even-mode; wherein, in this example, the equal ripple order is the number of the coupled lines;

step 3, the class I Chebyshev polynomial T_{N}=2xT_{N-1}(x)−T_{N-2}(x) in the same order is calculated according to the equal ripple order determined in step 1; wherein, T₀(χ)=1; T₁(χ)=χ;

step 4, according to the ABCD matrix expression and the Chebyshev polynomial calculated in step 2 and step 3, equivalent conditions of the ABCD matrix expression and the Chebyshev polynomial ae calculated, that is, the circuit in the present application satisfies the structure of the Chebyshev polynomial by equaling the transmission function S₂₁ calculated through the even-mode ABCD matrix of the N cascaded coupled line units to the transmission function S₂₁ calculated through the Chebyshev polynomial;

step 5, the even-mode impedance value of each section of coupled line Zᵢₑ (Z₁ₑ, Z₂ₑ, Z₃ₑ . . . ) according to the equivalent conditions calculated in step 4;

step 6, from the analysis formula and image of the reflection function S₁₁, each zero position of the reflection function S₁₁ and the peak (namely a position where the derivation is 0 of each ripple are determined;

step 7, under odd-mode analysis, the source terminal impedance Zs of the circuit is 0Ω, and the load terminal impedance Z_{L} of the circuit is 50Ω; through the constraint condition determined under the odd-mode condition zero positions of the isolation function S₃₂ and the reflection function S₁₁ and peaks (namely position where the derivation is 0) of ripples are the same;

step 8, the odd-mode impedance value Zᵢₒ (Z₁ₒ, Z₂ₒ, Z₃ₒ . . . ) of each section of coupled line and the impedance value of each isolation resistor Rᵢ are obtained according to the constraint conditions calculated in step 7;

step 9, all the obtained impedance values are put into the model to obtain a final circuit.

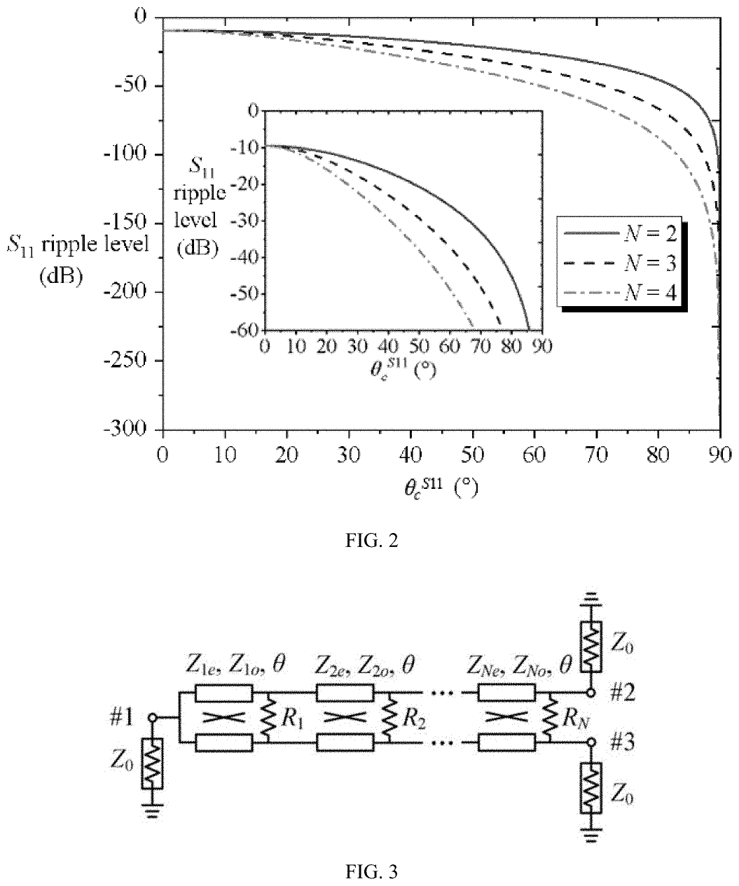

First, the number of sections of the ultra wide band Wilkinson power divider should be determined according to actual bandwidth requirements, as shown in FIG. 2, under the even-mode condition, the number of sections restrains the Chebyshev ripple order and the electrical length θ_{c}^{S11}; after the number of sections is determined, the ripple height and the electrical length θ_{c}^{S11} are a pair of causal variables.

In this example, as shown in FIG. 3, the power divider is composed of N cascaded units, each unit is composed of one section of coupled line and one isolation resistor, and the resistor is connected between the coupled line; Zᵢₑ and Zᵢₒ are the even-mode characteristic impedance and the odd-mode characteristic impedance of the i^{th} section of coupled line, the electrical length of all the coupled lines is θ, Rᵢ is the isolation resistance of the i^{th} section of coupled line unit, and Zₛ and Z_{L} are the real terminal impedances of the power divider.

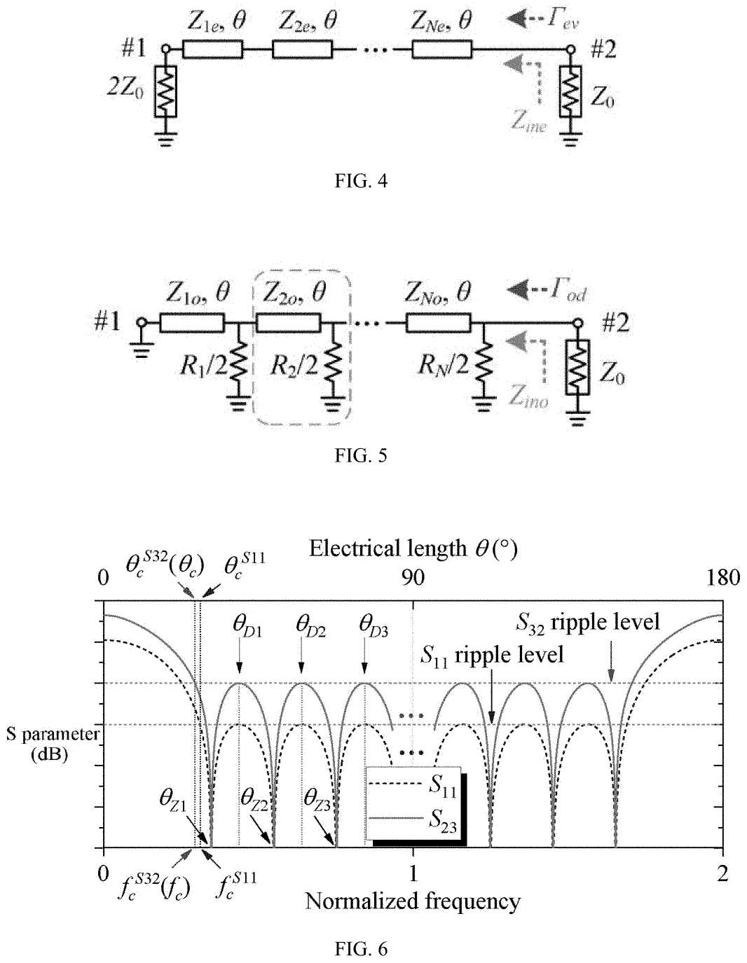

As shown in FIG. 4, under even-mode analysis, the ABCD matrix of the i^{th} coupled line unit is

$$[ \begin{matrix}{A}_{ie} & {B}_{ie} \\ {C}_{ie} & {D}_{ie}\end{matrix} ] = [ \begin{matrix}cos θ & {jZ}_{ie} sin θ \\ j sin θ / {Z}_{ie} & cos θ\end{matrix} ] \qquad ( 1 )$$

The even-mode ABCD matrix of the N cascaded coupled line units can be expanded as

$$[ \begin{matrix}{A}_{e v} & {B}_{e v} \\ {C}_{e ν} & {D}_{e v}\end{matrix} ] = [ \begin{matrix}{A}_{Ne} & {B}_{N e} \\ {C}_{N e} & {D}_{Ne}\end{matrix} ] … [ \begin{matrix}{A}_{2 e} & {B}_{2 e} \\ {C}_{2 e} & {D}_{2 e}\end{matrix} ] [ \begin{matrix}{A}_{1 e} & {B}_{1 e} \\ {C}_{1 e} & {D}_{1 e}\end{matrix} ] \qquad ( 2 )$$

wherein, when N is odd:

$${A}_{e v} = {a}_{N e} {cos}^{N} θ + … + {a}_{3 e} {cos}^{3} θ + {a}_{1 e} {cos}^{1} θ \\ {B}_{e v} = \frac{j}{sin θ} ( {b}_{N + 1 e} {cos}^{N + 1} θ + … + {b}_{2 e} {cos}^{2} θ + {b}_{0 e} {cos}^{0} θ )$$

$${C}_{e v} = \frac{j}{sin θ} ( {c}_{N + 1 e} {cos}^{N + 1} θ + … + {c}_{2 e} {cos}^{2} θ + {c}_{0 e} {cos}^{0} θ )$$

$${D}_{e v} = {d}_{N e} {cos}^{N} θ + … + {d}_{3 e} {cos}^{3} θ + {d}_{1 e} {cos}^{1} θ$$

when N is even:

$${A}_{ev} = {a}_{N e} {cos}^{N} θ + … + {a}_{2 e} {cos}^{2} θ + {a}_{0 e} {cos}^{0} θ \\ {B}_{e v} = \frac{j}{sin θ} ( {b}_{N + 1 e} {cos}^{N + 1} θ + … + {b}_{3 e} {cos}^{3} θ + {b}_{1 e} {cos}^{1} θ )$$

$${C}_{e v} = \frac{j}{sin θ} ( {c}_{N + 1 e} {cos}^{N + 1} θ + … + {c}_{3 e} {cos}^{3} θ + {c}_{1 e} {cos}^{1} θ )$$

$${D}_{e v} = {d}_{N e} {cos}^{N} θ + … + {d}_{2 e} {cos}^{2} θ + {d}_{0 e} {cos}^{0} θ$$

in the formulas, a_{Ne}, b_{Ne}, c_{Ne} and d_{Ne} are respectively polynomial coefficients whose numbers of times are n, (n∈0, 1, 2, . . . , N, N+1).

a_{Ne}, b_{Ne}, c_{Ne} and d_{Ne} are determined by characteristic impedances Zᵢₑ (i=1, 2 . . . , N), and the input impedance of port 2 Zᵢₙₑ can be deduced as

$${Z}_{ine} = \frac{{A}_{ev} \cdot 2 {Z}_{0} + {B}_{ev}}{{C}_{ev} \cdot 2 {Z}_{0} + {D}_{e v}} \qquad ( 4 )$$

According to the following formulas 21(a)˜(j), Aₑᵥ, Bₑᵥ, Cₑᵥ and Dₑᵥ are all formulas related to Zᵢₑ

the reflection coefficient Γₑᵥ of the port 2 under the even-mode condition is

$${Γ}_{e v} = \frac{{Z}_{ine} - {Z}_{0}}{{Z}_{ine} + {Z}_{0}} \qquad ( 5 )$$

The characteristic function Γₑᵥ is defined as

$$\begin{matrix}{F}_{e v} = \frac{{S}_{11}}{{S}_{Z 1}} = \frac{2 {A}_{ev} + {B}_{e v} / {Z}_{0} - 2 {Z}_{0} {C}_{e v} - {D}_{e v}}{2 \sqrt{2}} & ( 6 ) \\ {B}_{e v} / {Z}_{0} - 2 {Z}_{0} {C}_{e v} = 0 & ( 7 )\end{matrix}$$

Z₀ is a normalized impedance, namely, normalization is to divide the impedance by Z₀, so as to obtain 1Ω,

$${F}_{e v} = \frac{{S}_{11}}{{S}_{21}} = \frac{2 {A}_{ev} - {D}_{e v}}{2 \sqrt{2}} = \frac{1}{2 \sqrt{2}} {\sum }_{m}^{N} ( 2 {a}_{m e} - {d}_{m e} ) {cos}^{m} θ \qquad ( 8 )$$

Since the higher order polynomial Fₑᵥ is a function of cos θ, S₁₁ is constrained as a class I Chebyshev polynomial to achieve equal ripple response, namely, cos(Nφ)=T(x),

$$x = \frac{cos θ}{cos {θ}_{c}^{S 11}} ,$$

here

$$\vert {F}_{e v} \vert = ɛ \vert cos ( N ϕ ) \vert = ɛ \vert {\sum }_{n = 1}^{N} \frac{{cos}^{n} θ}{{cos}^{n} {θ}_{c}^{S 11}} \vert \qquad ( 9 )$$

in the formula, θ_{c}^{S11} is the electrical length of S₁₁ cut-off frequency, and ε is a ripple constant. θ_{c} is the electrical length of the lower frequency in the two cut-off frequencies of a filter. N is the order of a Chebyshev filter, namely, the number of sections of the coupled lines. φ is a deflecting concept replacing the electrical length, and is used to induce formulas.

ε={square root over (10^{0.1L}^{_{A}}−1)} (10)

In the formula, L_{A} is an in-band ripple factor, and the unit is dB;

The amplitude square transfer function can be written as:

$${\vert {S}_{21} \vert}^{2} = \frac{1}{1 + {\vert {F}_{ev} \vert}^{2}} = \frac{1}{1 + {ɛ}^{2} {\vert cos ( N ϕ ) \vert}^{2}} . \qquad ( 11 )$$

As shown in FIG. 5, under odd-mode analysis, compared with even-mode, the coupled line unit of the odd-mode is composed of one section of transmission line with a characteristic impedance as Zᵢₒ and one resistor with an impedance as R_{i/2}, and the coupling strength kᵢ of the i^{th} unit can be represented as

$${k}_{i} = - 201 g \frac{{Z}_{ie} - {Z}_{io}}{{Z}_{ie} + {Z}_{io}} ( i = 1 , 2 , … , N )$$

Under odd-mode analysis, the ABCD matrix of the i^{th} coupled line unit is

$$[ \begin{matrix}{A}_{io} & {B}_{io} \\ {C}_{io} & {D}_{io}\end{matrix} ] = [ \begin{matrix}1 & 0 \\ 2 \text{/} {R}_{i} & 1\end{matrix} ] [ \begin{matrix}cos θ & {jZ}_{io} sin θ \\ j sin θ \text{/} {Z}_{io} & cos θ\end{matrix} ] \qquad ( 12 )$$

The odd-mode ABCD matrix of the N cascaded coupled line units can be expanded as

$$[ \begin{matrix}{A}_{od} & {B}_{od} \\ {C}_{od} & {D}_{od}\end{matrix} ] = [ \begin{matrix}{A}_{No} & {B}_{No} \\ {C}_{No} & {D}_{No}\end{matrix} ] ⋯ [ \begin{matrix}{A}_{2 o} & {B}_{2 o} \\ {C}_{2 o} & {D}_{2 o}\end{matrix} ] [ \begin{matrix}{A}_{11 o} & {B}_{1 o} \\ {C}_{1 o} & {D}_{1 o}\end{matrix} ] \qquad ( 13 )$$

wherein, when N is odd:

$${A}_{od} = {a}_{Nor} {cos}^{N} θ + ⋯ + {a}_{3 or} {cos}^{3} θ + {a}_{1 or} {cos}^{1} θ + \frac{j}{sin θ} ( {a}_{N + 1 oi} {cos}^{N + 1} θ + ⋯ {a}_{2 oi} {cos}^{2} θ + {a}_{0 oi} {cos}^{0} θ )$$

$${B}_{od} = {b}_{Nor} {cos}^{N} θ + ⋯ + {b}_{3 or} {cos}^{3} θ + {b}_{1 or} {cos}^{1} θ + \frac{j}{sin θ} ( {b}_{N + 1 oi} {cos}^{N + 1} θ + ⋯ {b}_{2 oi} {cos}^{2} θ + {b}_{0 oi} {cos}^{0} θ )$$

$${C}_{od} = {c}_{Nor} {cos}^{N} θ + ⋯ + {c}_{3 or} {cos}^{3} θ + {c}_{1 or} {cos}^{1} θ + \frac{j}{sin θ} ( {c}_{N + 1 oi} {cos}^{N + 1} θ + ⋯ {c}_{2 oi} {cos}^{2} θ + {c}_{0 oi} {cos}^{0} θ )$$

$${D}_{od} = {d}_{Nor} {cos}^{N} θ + ⋯ + {d}_{3 or} {cos}^{3} θ + {d}_{1 or} {cos}^{1} θ + \frac{j}{sin θ} ( {d}_{N + 1 oi} {cos}^{N + 1} θ + ⋯ {d}_{2 oi} {cos}^{2} θ + {d}_{0 oi} {cos}^{0} θ )$$

when N is even:

$${A}_{od} = {a}_{Nor} {cos}^{N} θ + ⋯ + {a}_{2 or} {cos}^{2} θ + {a}_{0 or} {cos}^{0} θ + \frac{j}{sin θ} ( {a}_{N + 1 oi} {cos}^{N + 1} θ + ⋯ {a}_{3 oi} {cos}^{3} θ + {a}_{0 oi} {cos}^{1} θ )$$

$${B}_{od} = {b}_{Nor} {cos}^{N} θ + ⋯ + {b}_{2 or} {cos}^{2} θ + {b}_{0 or} {cos}^{0} θ + \frac{j}{sin θ} ( {b}_{N + 1 oi} {cos}^{N + 1} θ + ⋯ {b}_{3 oi} {cos}^{3} θ + {b}_{0 oi} {cos}^{1} θ )$$

$${C}_{od} = {c}_{Nor} {cos}^{N} θ + ⋯ + {c}_{2 or} {cos}^{2} θ + {c}_{0 or} {cos}^{0} θ + \frac{j}{sin θ} ( {c}_{N + 1 oi} {cos}^{N + 1} θ + ⋯ {c}_{3 oi} {cos}^{3} θ + {c}_{0 oi} {cos}^{1} θ )$$

$${D}_{od} = {d}_{Nor} {cos}^{N} θ + ⋯ + {d}_{2 or} {cos}^{2} θ + {d}_{0 or} {cos}^{0} θ + \frac{j}{sin θ} ( {d}_{N + 1 oi} {cos}^{N + 1} θ + ⋯ {d}_{3 oi} {cos}^{3} θ + {d}_{0 oi} {cos}^{1} θ )$$

In the formulas, a_{Nor}, b_{Nor}, c_{Nor} and d_{Nor} as well as a_{Noi}, b_{Noi}, c_{Noi} and d_{Noi} are respectively polynomial coefficients whose numbers of times are n (n∈0, 1, 2, . . . , N, N+1).

All the coefficients a_{Nor}, b_{Nor}, c_{Nor} and d_{Nor} as well as a_{Noi}, b_{Noi}, c_{Noi} and d_{Noi} are determined by the characteristic impedances Zᵢₒ and Rᵢ (i=1, 2, . . . , N), and the input impedance of the port 2 Zᵢₙₒ can be derived as

$${Z}_{ino} = \frac{{A}_{od} \cdot 0 + {B}_{od}}{{C}_{od} \cdot 0 + {D}_{od}} = \frac{{B}_{od}}{{D}_{od}} \qquad ( 15 )$$

According to the formulas 33 (a)˜34 (s), A_{od}, B_{od}, C_{od} and D_{od} are all formulas related to Zᵢₒ.

In each transmission zero of S₁₁, the formula (15) is required to reach the matching condition, that is, in each zero (θ_{Z1}, θ_{Z2}, θ_{Z3}), the formula (15) is equal to 50Ω; secondly, at frequency points (θ_{D1}, θ_{D2}, θ_{D3}) where ripples of S₁₁ are derived as 0, the formula (17) is required to be derived as 0 and has the same ripple height at these points, and the following three formulas are reduced as:

$${Z}_{ino} = 1 \vert \vert θ = {θ}_{Z 1} , {θ}_{Z 2} , {θ}_{Z 3} …$$

$${S}_{32} = \frac{{Γ}_{ev} - {Γ}_{od}}{2} = 0 \vert \vert θ = {θ}_{D 1} , {θ}_{D 2} , {θ}_{D 3} …$$

$$\frac{\partial ( {S}_{32} )}{\partial θ} = 0 \vert \vert θ = {θ}_{D 1} , {θ}_{D 2} , {θ}_{D 3} …$$

The reflection coefficient Γₑᵥ of the port 2 under the odd-even condition is

$${Γ}_{od} = \frac{{Z}_{ino} - {Z}_{0}}{{Z}_{ino} + {Z}_{0}} \qquad ( 16 )$$

Under the even-mode condition, the characteristic impedance Zᵢₑ(i=1, 2, . . . , N) of each coupled line unit is determined by the class I Chebyshev polynomial coefficients; under the odd-mode condition, the characteristic Zᵢₒ and the isolation resistance Rᵢ (i=1, 2, . . . , N) are used to achieve the equal ripple response of S₃₂.

The calculation formula of isolation response S₃₂ is

$${S}_{32} = \frac{{Γ}_{ev} - {Γ}_{od}}{2} \qquad ( 17 )$$

As shown in FIG. 6, for the convenience of design, the frequencies corresponding to the peaks of S₃₂ and S₁₁ ripples are consistent, and the frequencies corresponding to zeros are consistent. The return loss S₁₁ and isolation S₃₂ can be independently regulated.

In this example, θ_{Z1}, θ_{Z2}, θ_{Z3}, . . . , are defined as zero positions of S₁₁ and S₃₂, θ_{D1}, θ_{D2}, θ_{D3}, . . . , are positions where S₁₁ and S₃₂ are derived as 0, θ_{c}^{S32} and θ_{c}^{S11} are the electrical lengths corresponding to the cut-off frequencies of S₁₁ and S₃₂, and θ_{c}^{S32} and θ_{c}^{S11} are different;

Δθ_{c}=|θ_{c}^{S32}−θ_{c}^{S11}≠0 (18)

In the formula, Δθ_{c} is a smaller value determined by circuit parameters. In fact, the actual cut-off frequency f_{c} of the ultra wide band power divider is determined by θ_{c}^{S32} (or f_{c}^{S32}).

f_{c}=f_{c}^{S32} (19)

This means that the actual bandwidth of the power divider is narrower than the bandwidth under the even-mode condition, and this bandwidth should be carefully considered and handled in the process of designing the power divider.

### Examples

The disclosure will be specially further described by analyzing and establishing a three-section ultra wide band Wilkinson power divider.

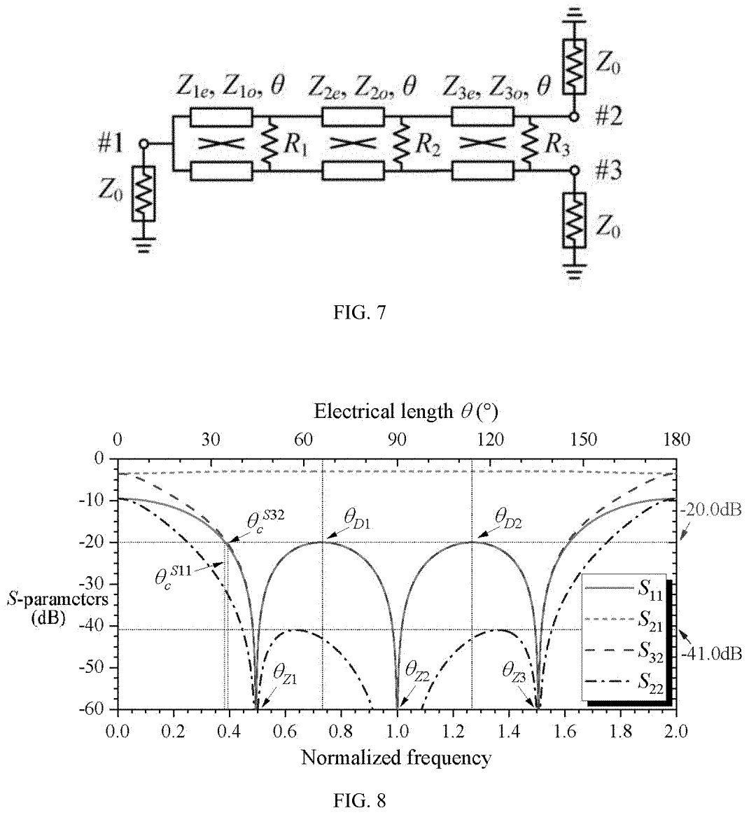

As shown in FIG. 7, according to the formulas (1) and (2), the ABCD matrix of the three-section ultra wide band Wilkinson power divider under the even-mode condition is

$$\begin{matrix}[ \begin{matrix}{A}_{ev} & {B}_{ev} \\ {C}_{ev} & {D}_{ev}\end{matrix} ] = [ \begin{matrix}{A}_{3 e} & {B}_{3 e} \\ {C}_{3 e} & {D}_{3 e}\end{matrix} ] [ \begin{matrix}{A}_{2 e} & {B}_{2 e} \\ {C}_{2 e} & {D}_{2 e}\end{matrix} ] [ \begin{matrix}{A}_{1 e} & {B}_{1 e} \\ {C}_{1 e} & {D}_{1 e}\end{matrix} ] & ( 20 ) \\ {A}_{ev} = {a}_{3 e} {cos}^{3} θ + {a}_{1 e} cos θ & ( 21 a ) \\ {B}_{ev} = \frac{j}{sin θ} ( {b}_{4 e} {cos}^{4} θ + {b}_{2 e} {cos}^{2} θ + {b}_{0 e} ) & ( 21 b ) \\ {C}_{ev} = \frac{j}{sin θ} ( {c}_{4 e} {cos}^{4} θ + {c}_{2 e} {cos}^{2} θ + {c}_{0 e} ) & ( 21 c ) \\ {D}_{ev} = {d}_{3 e} {cos}^{3} θ + {d}_{1 e} cos θ & ( 21 d ) \\ {a}_{3 e} = 1 + \frac{{Z}_{2 e}}{{Z}_{1 e}} + \frac{{Z}_{3 e}}{{Z}_{1 e}} + \frac{{Z}_{3 e}}{{Z}_{2 e}} & ( 22 a ) \\ {a}_{1 e} = - ( \frac{{Z}_{2 e}}{{Z}_{1 e}} + \frac{{Z}_{3 e}}{{Z}_{1 e}} + \frac{{Z}_{3 e}}{{Z}_{2 e}} ) & ( 22 b ) \\ {b}_{4 e} = - ( {Z}_{1 e} + {Z}_{2 e} + {Z}_{3 e} + \frac{{Z}_{1 e} {Z}_{3 e}}{{Z}_{2 e}} ) & ( 22 c ) \\ {b}_{2 e} = {Z}_{1 e} + {Z}_{2 e} + {Z}_{3 e} + \frac{2 {Z}_{1 e} {Z}_{3 e}}{{Z}_{2 e}} & ( 22 d ) \\ {b}_{0 e} = - \frac{{Z}_{1 e} {Z}_{3 e}}{{Z}_{2 e}} & ( 22 e ) \\ {c}_{4 e} = - ( \frac{1}{{Z}_{1 e}} + \frac{1}{{Z}_{2 e}} + \frac{1}{{Z}_{3 e}} + \frac{{Z}_{2 e}}{{Z}_{1 e} {Z}_{3 e}} ) & ( 22 f ) \\ {c}_{2 e} = \frac{1}{{Z}_{1 e}} + \frac{1}{{Z}_{2 e}} + \frac{1}{{Z}_{3 e}} + \frac{2 {Z}_{2 e}}{{Z}_{1 e} {Z}_{3 e}} & ( 22 g ) \\ {c}_{0 e} = - \frac{{Z}_{2 e}}{{Z}_{1 e} {Z}_{3 e}} & ( 22 h ) \\ {d}_{3 e} = 1 + \frac{{Z}_{1 e}}{{Z}_{2 e}} + \frac{{Z}_{1 e}}{{Z}_{3 e}} + \frac{{Z}_{2 e}}{{Z}_{3 e}} & ( 22 i ) \\ {d}_{1 e} = - ( \frac{{Z}_{1 e}}{{Z}_{2 e}} + \frac{{Z}_{1 e}}{{Z}_{3 e}} + \frac{{Z}_{2 e}}{{Z}_{3 e}} ) & ( 22 j )\end{matrix}$$

The amplification square transfer function under the design condition (Z₀=1Ω)

Bₑᵥ−2Cₑᵥ=0 (23)

Under the even-mode condition can be written as

$${\vert {S}_{21} \vert}^{2} = \frac{1}{1 + {\vert {F}_{ev} \vert}^{2}} = \frac{1}{1 + {\vert {t}_{3} {cos}^{3} θ + t cos θ \vert}^{2}} \qquad ( 24 )$$

Fₑᵥ is the characteristic function;

$$\begin{matrix}{t}_{3} = \frac{1}{2 \sqrt{2}} ( 2 {a}_{3 e} - {d}_{3 e} ) & ( 25 a ) \\ {t}_{1} = \frac{1}{2 \sqrt{2}} ( 2 {a}_{1 e} - {d}_{1 e} ) & ( 25 b )\end{matrix}$$

Since the number of sections N=3, the following equations are deduced according to the Chebyshev polynomial

$$\begin{matrix}cos 3 ϕ = \frac{4}{{cos}^{3} {θ}_{c}^{S 11}} {cos}^{3} θ - \frac{3}{cos {θ}_{c}^{S 11}} cos θ & ( 26 ) \\ \vert {F}_{ev} \vert = \vert {t}_{3} {cos}^{3} θ + t cos θ \vert = ɛ \vert cos 3 ϕ \vert & ( 27 )\end{matrix}$$

Finally, they are deduced as

$$\begin{matrix}{b}_{4 e} - 2 {c}_{4 e} = 0 & ( 28 a ) \\ {b}_{2 e} - 2 {c}_{2 e} = 0 & ( 28 b ) \\ {b}_{0 e} - 2 {c}_{0 e} = 0 & ( 28 c ) \\ \frac{1}{2 \sqrt{2}} ( 2 {a}_{3 e} - {d}_{3 e} ) = \frac{4 ɛ}{{cos}^{3} {θ}_{c}^{S 11}} & ( 28 d ) \\ \frac{1}{2 \sqrt{2}} ( 2 {a}_{1 e} - {d}_{1 e} ) = - \frac{3 ɛ}{cos {θ}_{c}^{S 11}} & ( 28 e )\end{matrix}$$

According to formula (28), the even mode characteristic impedances Z₁ₑ, Z₂ₑ and Z₃ₑ can be obtained, thus the input impedance Zᵢₙₑ seen from the port 2 under the even-mode condition can be obtained.

$${Z}_{ine} = \frac{{A}_{e v} \cdot 2 {Z}_{0} + {B}_{e v}}{{C}_{e v} \cdot 2 {Z}_{0} + {D}_{e v}} = \frac{2 {Z}_{0} ( {a}_{3 e} {cos}^{3} θ + {a}_{1 e} cos θ ) + \frac{j}{sin θ} ( {b}_{4 e} {cos}^{4} θ + {b}_{2 e} {cos}^{2} θ + {b}_{0 e} )}{{d}_{3 e} {cos}^{3} θ + {d}_{1 e} cos θ + 2 {Z}_{0} \frac{f}{sin θ} ( {c}_{4 e} {cos}^{4} θ + {c}_{2 e} {cos}^{2} θ + {c}_{0 e} )} . \qquad ( 29 )$$

the reflection coefficient δₑᵥ seen from the port 2 under the even-mode condition is

$$\begin{matrix} {Γ}_{e v} = \frac{{Z}_{ine} - {Z}_{0}}{{Z}_{ine} + {Z}_{0}} = \frac{{P}_{e v}}{{Q}_{e v}} & ( 30 ) \\ {P}_{e v} = ( 2 {a}_{3 e} {Z}_{0} - {d}_{3 e} {Z}_{0} ) {cos}^{3} θ + ( 2 {a}_{1 e} {Z}_{0} - {d}_{1 e} {Z}_{0} ) cos θ + \frac{j}{sin θ} ( ( {b}_{4 e} - 2 {c}_{4 e} {Z}_{0}^{2} ) {cos}^{4} θ + ( {b}_{2 e} - 2 {c}_{2 e} {Z}_{0}^{2} ) {cos}^{2} θ + ( {b}_{0 e} - 2 {c}_{0 e} {Z}_{0}^{2} ) ) & ( 31 a ) \\ {Q}_{e v} = ( 2 {a}_{3 e} {Z}_{0} + {d}_{3 e} {Z}_{0} ) {cos}^{3} θ + ( 2 {a}_{1 e} {Z}_{0} + {d}_{1 e} {Z}_{0} ) cos θ + \frac{j}{sin θ} ( ( {b}_{4 e} + 2 {c}_{4 e} {Z}_{0}^{2} ) {cos}^{4} θ + ( {b}_{2 e} + 2 {c}_{2 e} {Z}_{0}^{2} ) {cos}^{2} θ + ( {b}_{0 e} + 2 {c}_{0 e} {Z}_{0}^{2} ) ) & ( 31 b )\end{matrix}$$

Under the odd-even condition, the ABCD transmission matrix is represented as

$$\begin{matrix} [ \begin{matrix}{A}_{od} & {B}_{od} \\ {C}_{od} & {D}_{od}\end{matrix} ] = [ \begin{matrix}{A}_{3 o} & {B}_{3 o} \\ {C}_{3 o} & {D}_{3 o}\end{matrix} ] [ \begin{matrix}{A}_{2 o} & {B}_{2 o} \\ {C}_{2 o} & {D}_{2 o}\end{matrix} ] [ \begin{matrix}{A}_{1 o} & {B}_{1 o} \\ {C}_{1 o} & {D}_{1 o}\end{matrix} ] \\ wherein & ( 32 ) \\ {A}_{od} = {a}_{3 or} {cos}^{3} θ + {a}_{1 or} cos θ + \frac{j}{sin θ} ( {a}_{4 oi} {cos}^{4} θ + {a}_{2 oi} {cos}^{2} θ + {a}_{0 oi} & ( 33 a ) \\ {B}_{od} = {b}_{3 or} {cos}^{3} θ + {b}_{1 or} cos θ + \frac{j}{sin θ} ( {b}_{4 oi} {cos}^{4} θ + {b}_{2 oi} {cos}^{2} θ + {b}_{0 oi} ) & ( 33 b ) \\ {C}_{od} = {c}_{3 or} {cos}^{3} θ + {c}_{1 or} cos θ + \frac{j}{sin θ} ( {c}_{4 oi} {cos}^{4} θ + {c}_{2 oi} {cos}^{2} θ + {c}_{0 oi} ) & ( 33 c ) \\ {D}_{od} = {d}_{3 or} {cos}^{3} θ + {d}_{1 or} cos θ + \frac{j}{sin θ} ( {d}_{4 oi} {cos}^{4} θ + {d}_{2 oi} {cos}^{2} θ + {d}_{0 oi} ) & ( 33 d ) \\ {a}_{3 or} = 1 + \frac{{Z}_{3 o}}{{Z}_{2 o}} + \frac{{Z}_{3 o}}{{Z}_{1 o}} + \frac{{Z}_{2 o}}{{Z}_{1 o}} + \frac{4 {Z}_{2 o} {Z}_{3 o}}{{R}_{1} {R}_{2}} & ( 34 a ) \\ {a}_{1 or} = - ( \frac{{Z}_{3 o}}{{Z}_{2 o}} + \frac{{Z}_{3 o}}{{Z}_{1 o}} + \frac{{Z}_{2 o}}{{Z}_{1 o}} + \frac{4 {Z}_{2 o} {Z}_{3 o}}{{R}_{1} {R}_{2}} ) & ( 34 b ) \\ {a}_{2 or} = \frac{2 {Z}_{2 o}}{{R}_{1}} + \frac{2 {Z}_{3 o}}{{R}_{1}} + \frac{2 {Z}_{3 o}}{{R}_{2}} + \frac{2 {Z}_{2 o} {Z}_{3 o}}{{R}_{1} {Z}_{1 o}} & ( 34 c ) \\ {a}_{0 oi} = - \frac{2 {Z}_{2 o} {Z}_{3 o}}{{R}_{2} {Z}_{1 o}} & ( 34 d ) \\ {b}_{3 or} = \frac{2 {Z}_{1 o} {Z}_{2 o}}{{R}_{1}} + \frac{2 {Z}_{1 o} {Z}_{3 o}}{{R}_{1}} + \frac{2 {Z}_{1 o} {Z}_{3 o}}{{R}_{2}} + \frac{2 {Z}_{2 o} {Z}_{3 o}}{{R}_{2}} & ( 34 e ) \\ {b}_{1 or} = - ( \frac{2 {Z}_{1 o} {Z}_{2 o}}{{R}_{1}} + \frac{2 {Z}_{1 o} {Z}_{3 o}}{{R}_{1}} + \frac{2 {Z}_{1 o} {Z}_{3 o}}{{R}_{2}} + \frac{2 {Z}_{2 o} {Z}_{3 o}}{{R}_{2}} ) & ( 34 f ) \\ {b}_{4 oi} = - ( {Z}_{1 o} + {Z}_{2 o} + {Z}_{3 o} + \frac{2 {Z}_{1 o} {Z}_{3 o}}{{Z}_{2 o}} + \frac{4 {Z}_{1 o} {Z}_{2 o} {Z}_{3 o}}{{R}_{1} {R}_{2}} ) & ( 34 g ) \\ {b}_{2 oi} = {Z}_{1 o} + {Z}_{2 o} + {Z}_{3 o} + \frac{2 {Z}_{1 o} {Z}_{3 o}}{{Z}_{2 o}} + \frac{8 {Z}_{1 o} {Z}_{2 o} {Z}_{3 o}}{{R}_{1} {R}_{2}} & ( 34 h ) \\ {b}_{0 oi} = - ( \frac{{Z}_{1 o} {Z}_{3 o}}{{Z}_{2 o}} + \frac{4 {Z}_{1 o} {Z}_{2 o} {Z}_{3 o}}{{R}_{1} {R}_{2}} ) & ( 34 i ) \\ {c}_{3 or} = \frac{2}{{R}_{1}} + \frac{2}{{R}_{2}} + \frac{2}{{R}_{3}} + \frac{2 {Z}_{2 o}}{{R}_{2} {Z}_{1 o}} + \frac{2 {Z}_{2 o}}{{R}_{1} {Z}_{1 o}} + \frac{2 {Z}_{2 o}}{{R}_{3} {Z}_{1 o}} + \frac{2 {Z}_{3 o}}{{R}_{3} {Z}_{1 o}} + \frac{2 {Z}_{3 o}}{{R}_{3} {Z}_{2 o}} + \frac{8 {Z}_{2 o} {Z}_{3 o}}{{R}_{1} {R}_{2} {R}_{3}} & ( 34 j ) \\ {c}_{1 or} = - ( \frac{2 {Z}_{2 o}}{{R}_{2} {Z}_{1 o}} + \frac{2 {Z}_{2 o}}{{R}_{1} {Z}_{3 o}} + \frac{2 {Z}_{2 o}}{{R}_{3} {Z}_{1 o}} + \frac{2 {Z}_{3 o}}{{R}_{3} {Z}_{1 o}} + \frac{2 {Z}_{3 o}}{{R}_{3} {Z}_{2 o}} + \frac{8 {Z}_{2 o} {Z}_{3 o}}{{R}_{1} {R}_{2} {R}_{3}} ) & ( 34 k ) \\ {c}_{4 or} = - ( \frac{1}{{Z}_{1 o}} + \frac{1}{{Z}_{2 o}} + \frac{1}{{Z}_{3 o}} + \frac{4 {Z}_{2 o}}{{R}_{1} {R}_{2}} + \frac{4 {Z}_{2 o}}{{R}_{1} {R}_{2}} + \frac{4 {Z}_{2 o}}{{R}_{1} {R}_{3}} + \frac{4 {Z}_{3 o}}{{R}_{1} {R}_{3}} + \frac{4 {Z}_{3 o}}{{R}_{2} {R}_{3}} + \frac{{Z}_{2 o}}{{Z}_{1 o} {Z}_{3 o}} \frac{4 {Z}_{2 o} {Z}_{3 o}}{{R}_{2} {R}_{3} {Z}_{1 o}} ) & ( 34 l ) \\ {c}_{2 oi} = \frac{1}{{Z}_{1 o}} + \frac{1}{{Z}_{2 o}} + \frac{1}{{Z}_{3 o}} + \frac{4 {Z}_{2 o}}{{R}_{1} {R}_{2}} + \frac{4 {Z}_{2 o}}{{R}_{1} {R}_{3}} + \frac{4 {Z}_{3 o}}{{R}_{1} {R}_{3}} + \frac{4 {Z}_{3 o}}{{R}_{2} {R}_{3}} + \frac{2 {Z}_{2 o}}{{Z}_{1 o} {Z}_{3 o}} + \frac{8 {Z}_{2 o} {Z}_{3 o}}{{R}_{2} {R}_{3} {Z}_{1 o}} & ( 34 m ) \\ {c}_{0 oi} = - ( \frac{{Z}_{2 o}}{{Z}_{1 o} {Z}_{3 o}} + \frac{4 {Z}_{2 o} {Z}_{3 o}}{{R}_{2} {R}_{3} {Z}_{1 o}} ) & ( 34 n ) \\ {d}_{3 or} = 1 + \frac{{Z}_{1 o}}{{Z}_{2 o}} + \frac{{Z}_{1 o}}{{Z}_{3 o}} + \frac{{Z}_{2 o}}{{Z}_{3 o}} + \frac{4 {Z}_{1 o} {Z}_{2 o}}{{R}_{1} {R}_{2}} + \frac{4 {Z}_{1 o} {Z}_{2 o}}{{R}_{1} {R}_{3}} + \frac{4 {Z}_{1 o} {Z}_{3 o}}{{R}_{1} {R}_{3}} + \frac{4 {Z}_{1 o} {Z}_{3 o}}{{R}_{2} {R}_{3}} + \frac{4 {Z}_{2 o} {Z}_{3 o}}{{R}_{2} {R}_{3}} & ( 34 o ) \\ {d}_{1 or} = - ( \frac{{Z}_{1 o}}{{Z}_{2 o}} + \frac{{Z}_{1 o}}{{Z}_{3 o}} + \frac{{Z}_{2 o}}{{Z}_{3 o}} + \frac{4 {Z}_{1 o} {Z}_{2 o}}{{R}_{1} {R}_{2}} + \frac{4 {Z}_{1 o} {Z}_{2 o}}{{R}_{1} {R}_{3}} + \frac{4 {Z}_{1 o} {Z}_{3 o}}{{R}_{1} {R}_{3}} + \frac{4 {Z}_{1 o} {Z}_{3 o}}{{R}_{2} {R}_{3}} + \frac{4 {Z}_{2 o} {Z}_{3 o}}{{R}_{2} {R}_{3}} ) & ( 34 p ) \\ {d}_{4 oi} = - ( \frac{2 {Z}_{1 o}}{{R}_{1}} + \frac{2 {Z}_{1 o}}{{R}_{2}} + \frac{2 {Z}_{2 o}}{{R}_{2}} + \frac{2 {Z}_{1 o}}{{R}_{3}} + \frac{2 {Z}_{2 o}}{{R}_{3}} + \frac{2 {Z}_{3 o}}{{R}_{3}} + \frac{2 {Z}_{1 o} {Z}_{2 o}}{{R}_{1} {Z}_{3 o}} + \frac{2 {Z}_{1 o} {Z}_{3 o}}{{R}_{3} {Z}_{2 o}} + \frac{8 {Z}_{1 o} {Z}_{2 o} {Z}_{3 o}}{{R}_{1} {R}_{2} {R}_{3}} ) & ( 34 q ) \\ {d}_{2 oi} = \frac{2 {Z}_{1 o}}{{R}_{1}} + \frac{2 {Z}_{1 o}}{{R}_{2}} + \frac{2 {Z}_{2 o}}{{R}_{2}} + \frac{2 {Z}_{1 o}}{{R}_{3}} + \frac{2 {Z}_{2 o}}{{R}_{3}} + \frac{2 {Z}_{3 o}}{{R}_{3}} + \frac{4 {Z}_{1 o} {Z}_{2 o}}{{R}_{1} {Z}_{3 o}} + \frac{4 {Z}_{1 o} {Z}_{3 o}}{{R}_{3} {Z}_{2 o}} + \frac{16 {Z}_{1 o} {Z}_{2 o} {Z}_{3 o}}{{R}_{1} {R}_{2} {R}_{3}} & ( 34 r ) \\ {d}_{0 oi} = - ( \frac{2 {Z}_{1 o} {Z}_{2 o}}{{R}_{1} {Z}_{3 o}} + \frac{2 {Z}_{1 o} {Z}_{3 o}}{{R}_{3} {Z}_{2 o}} + \frac{8 {Z}_{1 o} {Z}_{2 o} {Z}_{3 o}}{{R}_{1} {R}_{2} {R}_{3}} ) & ( 34 s )\end{matrix}$$

The input impedance Zᵢₙₒ seen from the port 2 under the odd-mode condition

$${Z}_{ino} = \frac{{B}_{o d}}{{D}_{od}} = \frac{{b}_{3 o r} {cos}^{3} θ + {b}_{1 o r} cos θ + \frac{j}{sin θ} ( {b}_{4 oi} {cos}^{4} θ + {b}_{2 oi} {cos}^{2} θ + {b}_{0 oi} )}{{d}_{3 or} {cos}^{3} θ + {d}_{1 o r} cos θ + \frac{J}{sin θ} ( {d}_{4 oi} {cos}^{4} θ + {d}_{2 oi} {cos}^{2} θ + {d}_{0 oi} )} \qquad ( 35 )$$

the reflection coefficient Γ_{od} seen from the port 2 under the even-mode condition is

$$\begin{matrix} {Γ}_{o d} = \frac{{Z}_{ino} - {Z}_{0}}{{Z}_{ino} + {Z}_{0}} = \frac{{P}_{∘ d}}{{Q}_{o d}} & ( 36 ) \\ {P}_{o d} = ( {b}_{3 o r} - {d}_{3 o r} {Z}_{0} ) {cos}^{3} θ + ( {b}_{1 o r} - {d}_{1 o r} {Z}_{0} ) cos θ + \frac{j}{sin θ} ( ( {b}_{4 oi} - {d}_{4 oi} {Z}_{0} ) {cos}^{4} θ + ( {b}_{2 oi} - {d}_{2 oi} {Z}_{0} ) {cos}^{2} θ + ( {b}_{0 oi} - {d}_{0 oi} {Z}_{0} ) ) & ( 37 a ) \\ {Q}_{o d} = ( {b}_{3 o r} + {d}_{3 o r} {Z}_{0} ) {cos}^{3} θ + ( {b}_{1 or} + {d}_{1 o r} {Z}_{0} ) cos θ + \frac{j}{sin θ} ( ( {b}_{4 oi} + {d}_{4 oi} {Z}_{0} ) {cos}^{4} θ + ( {b}_{2 oi} + {d}_{2 oi} {Z}_{0} ) {cos}^{2} θ + ( {b}_{0 oi} + {d}_{0 oi} {Z}_{0} ) ) & ( 37 b )\end{matrix}$$

According to formulas (28) and (34), the isolation S₃₂ between the ports 2 and 3 can be obtained

$${S}_{32} = \frac{{Γ}_{e v} - {Γ}_{od}}{2} = \frac{{P}_{e v} {Q}_{od} - {P}_{o d} {Q}_{e v}}{2 {Q}_{e v} {Q}_{o d}} \qquad ( 38 )$$

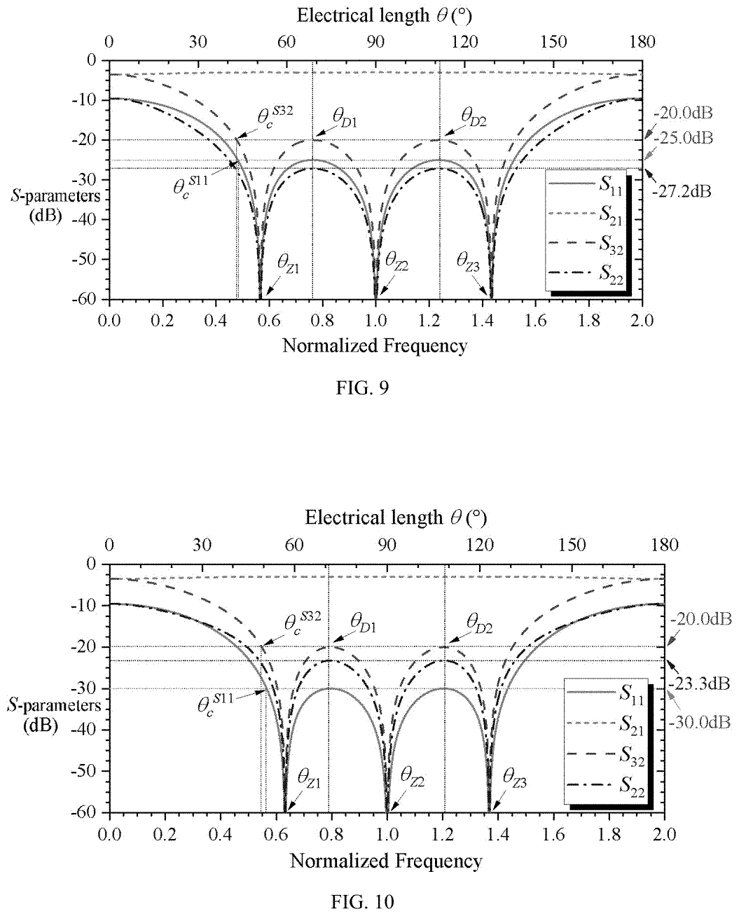

As shown in FIG. 8-10, because there are six additional parameters (characteristic impedances Z₁ₒ, Z₂ₒ, Z₃ₒ, isolation resistances R₁, R₂, R₃) under the odd-mode condition, θ_{D1} of S₃₂ and θ_{Z1} of S₃₂ are consistent with those of S₁₁. In order to provide flexible circuit design, the ripple heights of S₁₁ and S₃₂ (ripple height, namely, the point position where the derivation is 0, that is, the peak position of the ripple-θ_{Di}), can be independently regulated. Examples 1˜3 are designed as shown in Table 1. In examples 1˜3, k₃=−20 dB, and Z₀=1Ω;

TABLE 1
Design conditions of S₁₁ and S₃₂ of
power divider at different ripple grades

| | | Ripple grade (dB) | | |
|---|---|---|---|---|
| | | Example 1 | Example 2 | Example 3 |
| | | S₁₁ = −20 | S₁₁ = −25 | S₁₁ = −30 |
| | | S₃₂ = −20 | S₃₂ = −20 | S₃₂ = −20 |
| Characteristic impedance | Z₁ₑ (Ω) | 1.6744 | 1.7309 | 1.7665 |
| and coupling strength | Z₁ₒ (Ω) | 0.8572 | 0.2309 | 0.0758 |
| | k₁ (dB) | −9.82 | −2.33 | −0.75 |
| | Z₂ₑ (Ω) | 1.4142 | 1.4142 | 1.4142 |
| | Z₂ₒ (Ω) | 1.2324 | 0.5870 | 0.3260 |
| | k₂ (dB) | −23.26 | −7.67 | −4.08 |
| | Z₃ₑ (Ω) | 1.1945 | 1.1555 | 1.1322 |
| | Z₃ₒ (Ω) | 0.9773 | 0.9454 | 0.9263 |
| Isolation resistance | R₁ (Ω) | 2.01 | 0.84 | 0.41 |
| | R₂ (Ω) | 2.81 | 3.17 | 3.33 |
| | R₃ (Ω) | 8.43 | 5.06 | 3.69 |
| Electrical length | θ_{c}^{S11} (°) | 34.56 | 43.35 | 50.88 |
| | θ_{c}^{S32} (°) | 35.14 | 43.02 | 49.33 |
| | Δθ_{c} | 0.58 | 0.32 | 1.55 |

### Test Example

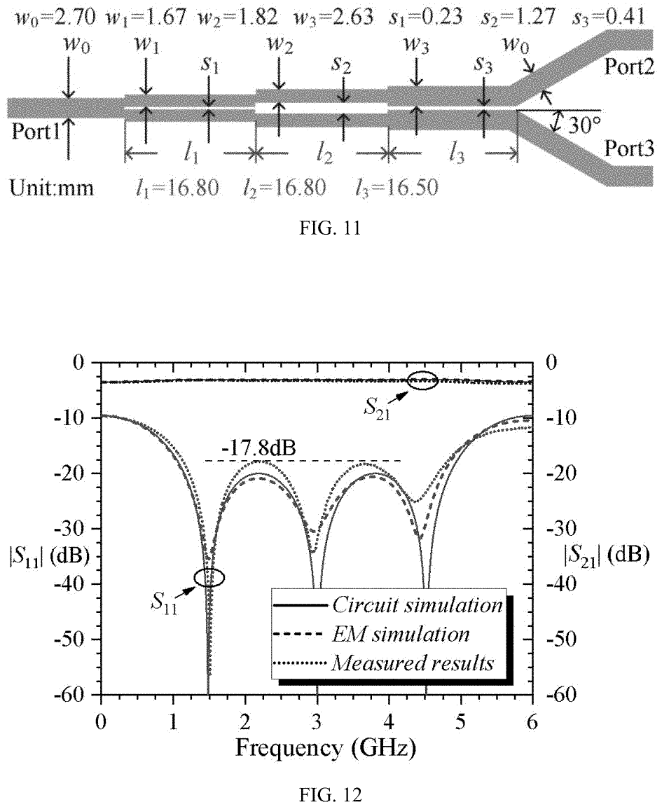

According to the above data in examples 1˜3, as shown in FIG. 11, data for establishing the ultra wide band class I Chebyshev multi-section Wilkinson power divider having equal ripple isolation characteristic is shown in Table 2 (in which the used substrate material is NPC F260A);

TABLE 2
Characteristic impedance

| Theoretical value (Ω) | Physical size (mm) |
|---|---|
| Z₁ₑ = 83.72, Z₁ₒ = 43.87 | W₁ = 1.67, S₁ = 0.23, L₁ = 16.80 |
| Z₂ₑ = 70.71, Z₂ₒ = 56.52 | W₁ = 1.82, S₁ = 1.27, L₁ = 16.80 |
| Z₃ₑ = 59.72, Z₃ₒ = 39.30 | W₁ = 2.63, S₁ = 0.41, L₁ = 16.50 |
| Z₀ = 50.00 | W₀ = 2.70 |

Isolation resistance

| Theoretical value (Ω) | Actual resistance value (Ω) |
|---|---|
| R₁ = 90.64 | 91 |
| R₂ = 109.97 | 110 |
| R₃ = ∞ | None |

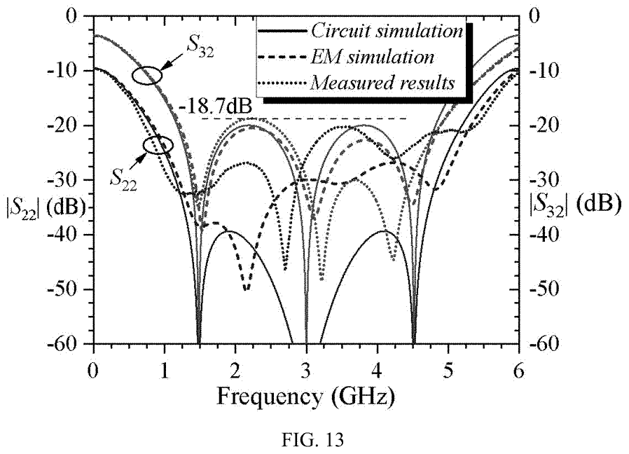

As shown in FIG. 12, S₂₁ of simulation is basically matched with S₂ of the test result, and S₁₁ simulation and the test result are within an allowable error range; as shown in FIG. 13, the ripple peaks of S₂₂ and S₃₂ are both basically compressed at about −20 dB designed by theoretical simulation. Therefore, the test bandwidth of each S parameter in the drawing basically conforms to that of theoretical design. Based on the analysis of the above results, the theory proposed in this patent is correct and feasible.

The embodiments of the disclosure have been disclosed as above but are not limited to applications listed in the specification and the embodiments. They can be applicable to various fields suitable for the disclosure, and those skilled in the art can easily achieve another amendments. Therefore, the disclosure is not limited to special details and figures shown and described herein without departing from the general concept defined by the claims and the equivalent scope.

We claim:

1. A method for establishing an ultra wide band (UWB) class I Chebyshev multi-section Wilkinson power divider having equal ripple isolation characteristic, comprising the following steps:
step 1, determining a Chebyshev equal ripple order required in the designed circuit and calculating a class I Chebyshev polynomial in the same order, and meanwhile determining the equal ripple heights of reflection function S₁₁ and isolation function S₃₂;
step 2, carrying out even mode analysis on the power divider, selecting a model according to the Chebyshev equal ripple order so as to calculate an ABCD matrix expression under the even-mode condition calculating equivalent conditions according to the ABCD matrix expression and the class I Chebyshev polynomial so that the designed circuit satisfies the structure of the Chebyshev polynomial and then a Zᵢₑ impedance value of each section of coupled line is obtained;
step 3, carrying out odd-mode analysis on the powder divider so that each zero position and each peak ripple position of the isolation function S₃₂ and the reflection function S₃₂ are the same, and then the Zᵢₒ impedance value of each section of coupled line and the impedance value of each isolation resistor are obtained; and
step 4, establishing a final circuit according to the Zᵢₑ impedance value, the Zᵢₒ impedance value and the impedance value of each isolation resistor.

2. The method for establishing an ultra wide band class I Chebyshev multi-section Wilkinson power divider having equal ripple isolation characteristic according to claim 1, wherein in the step 1, the Chebyshev equal ripple order is the number of the coupled lines.

3. The method for establishing an ultra wide band class I Chebyshev multi-section Wilkinson power divider having equal ripple isolation characteristic according to claim 2, wherein in the step 2, a coupled line unit is composed of one section of transmission line with a characteristic impedance as Zᵢₑ under the even-mode condition analysis.

4. The method for establishing an ultra wide band class I Chebyshev multi-section Wilkinson power divider having equal ripple isolation characteristic according to claim 1, wherein in the step 1, the class I Chebyshev polynomial is T_{N}=2×T_{N-1}(x)−T_{N-2}(x); wherein, T₀(χ)=1; T₁(χ)=χ.

5. The method for establishing an ultra wide band class I Chebyshev multi-section Wilkinson power divider having equal ripple isolation characteristic according to claim 3, wherein in the step 2, the even-mode ABCD matrix of N cascaded coupled line units is as follows:
$$[ \begin{matrix}{A}_{e v} & {B}_{e v} \\ {C}_{e v} & {D}_{e v}\end{matrix} ] = [ \begin{matrix}{A}_{N e} & {B}_{N e} \\ {C}_{N e} & {D}_{N e}\end{matrix} ] … [ \begin{matrix}{A}_{2 e} & {B}_{2 e} \\ {C}_{2 e} & {D}_{2 e}\end{matrix} ] [ \begin{matrix}{A}_{1 e} & {B}_{1 e} \\ {C}_{1 e} & {D}_{1 e}\end{matrix} ] ;$$
wherein, when N is odd:
$${A}_{ev} = {a}_{N e} {cos}^{N} θ + … + {a}_{3 e} {cos}^{3} θ + {a}_{1 e} {cos}^{1} θ \\ {B}_{e v} = \frac{j}{sin θ} ( {b}_{N + 1 e} {cos}^{N + 1} θ + … + {b}_{2 e} {cos}^{2} θ + {b}_{0 e} {cos}^{0} θ )$$
$${C}_{e v} = \frac{j}{sin θ} ( {c}_{N + 1 e} {cos}^{N + 1} θ + … + {c}_{2 e} {cos}^{2} θ + {c}_{0 e} {cos}^{0} θ )$$
$${D}_{e v} = {d}_{Ne} {cos}^{N} θ + … + {d}_{3 e} {cos}^{3} θ + {d}_{1 e} {cos}^{1} θ ;$$
when N is even:
$${A}_{ev} = {a}_{N e} {cos}^{N} θ + … + {a}_{2 e} {cos}^{2} θ + {a}_{0 e} {cos}^{0} θ \\ {B}_{e v} = \frac{j}{sin θ} ( {b}_{N + 1 e} {cos}^{N + 1} θ + … + {b}_{3 e} {cos}^{3} θ + {b}_{1 e} {cos}^{1} θ )$$
$${C}_{e v} = \frac{j}{sin θ} ( {c}_{N + 1 e} {cos}^{N + 1} θ + … + {c}_{3 e} {cos}^{3} θ + {c}_{1 e} {cos}^{1} θ )$$
$${D}_{e v} = {d}_{Ne} {cos}^{N} θ + … + {d}_{2 e} {cos}^{2} θ + {d}_{0 e} {cos}^{0} θ ;$$
in the formulas, a_{Ne}, b_{Ne}, c_{Ne} and d_{Ne} are respectively polynomial coefficients whose numbers of times are n (n∈0, 1, 2, N, N+1).

6. The method for establishing an ultra wide band class I Chebyshev multi-section Wilkinson power divider having equal ripple isolation characteristic according to claim 5, wherein in the step 2, the equivalent condition is that a transmission function S₂₁ calculated by the even-mode ABCD matrix of the N cascaded coupled line units is equal to a transmission function S₂₁ calculated through the Chebyshev polynomial.

7. The method for establishing an ultra wide band class I Chebyshev multi-section Wilkinson power divider having equal ripple isolation characteristic according to claim 6, wherein in the step 2, the source terminal impedance value Zₛ and the load terminal impedance value Z_{L} of the circuit are determined, and Z_{S}/Z_{L}=2; the transmission function S₂₁ calculated by the even-mode ABCD matrix of the N cascaded coupled line units is:
$${\vert {S}_{21} \vert}^{2} = \frac{1}{1 + {\vert {F}_{e v} \vert}^{2}} ;$$
$$wherein , {F}_{e v} = \frac{{S}_{11}}{{S}_{21}} = \frac{2 {A}_{e v} + {B}_{e v} / {Z}_{0} - 2 {Z}_{0} {C}_{e v} - {D}_{e v}}{2 \sqrt{2}} ;$$
and
the transmission function calculated by Chebyshev polynomial is:
$${\vert {S}_{21} \vert}^{2} = \frac{1}{1 + {\vert {F}_{e v} \vert}^{2}} ;$$
$$wherein , \vert {F}_{e v} \vert = ɛ \vert cos ( N ϕ ) \vert = ɛ \vert {\sum }_{n = 1}^{N} \frac{{cos}^{n} θ}{{cos}^{n} {θ}_{c}^{S 11}} \vert .$$

8. The method for establishing an ultra wide band class I Chebyshev multi-section Wilkinson power divider having equal ripple isolation characteristic according to claim 2, wherein in the step 3, the coupled line unit is composed of one section of transmission line with a characteristic impedance as Zᵢₒ and one resistor with an impedance as Rᵢ/2 under the condition of odd-mode analysis.

9. The method for establishing an ultra wide band class I Chebyshev multi-section Wilkinson power divider having equal ripple isolation characteristic according to claim 8, wherein in the step 3, the odd-mode ABCD matrix of the N cascaded coupled line units is:
$$[ \begin{matrix}{A}_{od} & {B}_{o d} \\ {C}_{o d} & {D}_{o d}\end{matrix} ] = [ \begin{matrix}{A}_{No} & {B}_{N o} \\ {C}_{No} & {D}_{No}\end{matrix} ] … [ \begin{matrix}{A}_{2 o} & {B}_{2 o} \\ {C}_{2 o} & {D}_{2 o}\end{matrix} ] [ \begin{matrix}{A}_{1 o} & {B}_{1 o} \\ {C}_{1 o} & {D}_{1 o}\end{matrix} ]$$
wherein, when N is odd:
$${A}_{o d} = {a}_{Nor} {cos}^{N} θ + … + {a}_{3 o r} {cos}^{3} θ + {a}_{1 o r} {cos}^{1} θ + \frac{j}{sin θ} ( {a}_{N + 1 oi} {cos}^{N + 1} θ + … {a}_{2 oi} {cos}^{2} θ + {a}_{0 oi} {cos}^{0} θ )$$
$${B}_{o d} = {b}_{N o r} {cos}^{N} θ + … + {b}_{3 or} {cos}^{3} θ + {b}_{1 or} {cos}^{1} θ + \frac{j}{sin θ} ( {b}_{N + 1 oi} {cos}^{N + 1} θ + … {b}_{2 oi} {cos}^{2} θ + {b}_{0 oi} {cos}^{0} θ )$$
$${C}_{od} = {c}_{N o r} {cos}^{N} θ + … + {c}_{3 o r} {cos}^{3} θ + {c}_{1 o r} {cos}^{1} θ + \frac{j}{sin θ} ( {c}_{N + 1 oi} {cos}^{N + 1} θ + … {c}_{2 oi} {cos}^{2} θ + {c}_{0 oi} {cos}^{0} θ )$$
$${D}_{o d} = {d}_{N o r} {cos}^{N} θ + … + {d}_{3 o r} {cos}^{3} θ + {d}_{1 or} {cos}^{1} θ + \frac{j}{sin θ} ( {d}_{N + 1 oi} {cos}^{N + 1} θ + … {d}_{2 oi} {cos}^{2} θ + {d}_{0 oi} {cos}^{0} θ )$$
when N is even:
$${A}_{o d} = {a}_{Nor} {cos}^{N} θ + … + {a}_{3 o r} {cos}^{3} θ + {a}_{1 o r} {cos}^{1} θ + \frac{j}{sin θ} ( {a}_{N + 1 oi} {cos}^{N + 1} θ + … {a}_{2 oi} {cos}^{2} θ + {a}_{0 oi} {cos}^{0} θ )$$
$${B}_{o d} = {b}_{N o r} {cos}^{N} θ + … + {b}_{3 or} {cos}^{3} θ + {b}_{1 or} {cos}^{1} θ + \frac{j}{sin θ} ( {b}_{N + 1 oi} {cos}^{N + 1} θ + … {b}_{2 oi} {cos}^{2} θ + {b}_{0 oi} {cos}^{0} θ )$$
$${C}_{od} = {c}_{N o r} {cos}^{N} θ + … + {c}_{3 o r} {cos}^{3} θ + {c}_{1 o r} {cos}^{1} θ + \frac{j}{sin θ} ( {c}_{N + 1 oi} {cos}^{N + 1} θ + … {c}_{2 oi} {cos}^{2} θ + {c}_{0 oi} {cos}^{0} θ )$$
$${D}_{o d} = {d}_{N o r} {cos}^{N} θ + … + {d}_{3 o r} {cos}^{3} θ + {d}_{1 or} {cos}^{1} θ + \frac{j}{sin θ} ( {d}_{N + 1 oi} {cos}^{N + 1} θ + … {d}_{2 oi} {cos}^{2} θ + {d}_{0 oi} {cos}^{0} θ )$$
in the formulas, a_{Nor}, b_{Nor}, c_{Nor} and d_{Nor} as well as a_{Noi}, b_{Noi}, c_{Noi} and d_{Noi} are respectively polynomial coefficients whose numbers of times are n, (n∈0, 1, 2, . . . , N, N+1).
